(19) United States
(12) Patent Application Publication
(10) Pub. No.: US 2018/0349962 A1
(43) Pub. Date: Dec. 6, 2018

(54) SYSTEM AND METHOD FOR USING ELECTROMAGNETIC NOISE SIGNAL-BASED PREDICTIVE ANALYTICS FOR DIGITAL ADVERTISING

(71) Applicant: International Business Machines Corporation, Armonk, NY (US)

(72) Inventors: Darryl M. Adderly, Morrisville, NC (US); Ea-Ee Jan, Ardsley, NY (US); Rosanna S. Mannan, San Jose, CA (US); Kevin L. Schultz, Raleigh, NC (US); Graham J. Wills, Naperville, IL (US)

(21) Appl. No.: 15/613,367

(22) Filed: Jun. 5, 2017

(51) Int. Cl. G06Q 30/02; G01R 29/08

(52) U.S. Cl. CPC G06Q 30/0269; G06N 7/005; G01R 29/0892

(57) ABSTRACT

A method and associated computer program product for providing targeted digital advertisements to a user. The method includes receiving a detected electromagnetic noise signal of one or more objects, comparing the detected electromagnetic noise signal to one or more stored electromagnetic noise signals associated with one or more objects, and determining an identity of the one or more objects based on the comparison between the detected electromagnetic noise signal the stored electromagnetic noise signals. The method further includes providing targeted digital advertisement(s) to the user based on the determined identity of the one or more objects.

### BACKGROUND OF THE INVENTION

The present disclosure relates generally to the fields of data analytics and digital advertising, and more particularly to analyzing electromagnetic (EM) noise signal data to determine and/or predict user touch events, and utilizing the electromagnetic noise signal data to construct a characteristic user profile and/or user classification to deliver targeted digital advertising to the user.

Predictive analytics is an area of data mining that deals with extracting information from data and using the information to predict trends and behavior patterns. Often, the unknown event of interest is in the future, but predictive analytics can be applied to any type of unknown, whether it be in the past, present or future. Predictive analytics encompasses a variety of statistical techniques from modeling, machine learning, and data mining that analyze current and historical facts to make predictions about future, or otherwise unknown events. The core of predictive analytics relies on determining relationships between explanatory variables and predictive variables from past occurrences, and using them to predict a future event.

One area in which predictive analytics is commonly used is targeted digital advertising. Often, a user's internet browser and/or search engine query history are determined to estimate the user's demographic profile and/or interests. For instance, if a user visits a particular website and/or views a particular product, service, event, etc., a “cookie” may be stored on the user's computer, wherein the cookie provides information regarding the user's browsing history. From this browsing history, a targeted banner advertisement or other form of digital advertisement for a product, service, event, etc., that is the same as, similar to, or related to that which was previously viewed may be delivered to the user. In this way, data related to the user's internet browser and/or search engine query history is used by advertisers to create an estimated profile of the user, thereby enabling the advertisers to present digital advertisements customized to this estimated profile.

Electromagnetic (EM) noise signal detection is the detection of the EM noise that an object produces or captures from nearby electronic and electromechanical objects. Electronic and electromechanical objects commonly emit EM noise during operation. Non-electronic and non-electromechanical objects, such as large structural objects like doors, window frames, and furniture, may also have unique EM noise signals by acting as antennas that capture and propagate EM noise from nearby electronic and electromechanical devices. Objects emitting or conducting EM noise can have unique signal characteristics, making it possible to differentiate one object from another. EM noise signal emission may be intentional, such as in cell phones, or unintentional, such as in power lines. In response to a user touching an EM noise signal emitting or conducting object, EM noise signals are conducted through the human body, which also acts as an antenna. The conducted EM noise signals can be detected by a radio receiver.

### SUMMARY

In accordance with an aspect of the disclosure, a method for providing one or more targeted digital advertisements to a user is disclosed. The method includes receiving, by one or more computer processors, a detected electromagnetic noise signal of one or more objects, and comparing, by the one or more computer processors, the detected electromagnetic noise signal of the one or more objects to one or more stored electromagnetic noise signals associated with one or more objects. The method also includes determining, by the one or more computer processors, an identity of the one or more objects based on the comparison between the detected electromagnetic noise signal of the one or more objects to one or more stored electromagnetic noise signals associated with one or more objects, and providing, by the one or more computer processors, one or more targeted digital advertisements to the user based on the determined identity of the one or more objects.

In accordance with another aspect of the disclosure, a computer program product for providing one or more targeted digital advertisements to a user is disclosed. The computer program product includes one or more computer readable storage devices having a non-transitory, computer-readable memory containing program instructions stored thereon, the stored program instructions including program instructions to receive a detected electromagnetic noise signal of one or more objects, and program instructions to compare the detected electromagnetic noise signal of the one or more objects to one or more stored electromagnetic noise signals associated with one or more objects. Based, at least in part, on the comparison, the computer program product also includes program instructions to determine an identity of the one or more objects, and based, at least in part, on the determined identity of the one or more objects, program instructions to provide one or more targeted digital advertisements to the user.

In accordance with another aspect of the disclosure, a computer system for providing one or more targeted digital advertisements to a user is disclosed. The computer system includes one or more computer processors, one or more computer readable storage devices, and program instructions stored on the one or more computer readable storage devices for execution by at least one of the one or more computer processors. The stored program instructions include program instructions to receive a detected electromagnetic noise signal of one or more objects, and program instructions to compare the detected electromagnetic noise signal of the one or more objects to one or more stored electromagnetic noise signals associated with one or more objects. Based, at least in part, on the comparison, the stored program instructions also include program instructions to determine an identity of the one or more objects, and based, at least in part, on the determined identity of the one or more objects, program instructions to provide one or more targeted digital advertisements to the user.

### BRIEF DESCRIPTION OF THE DRAWINGS

FIG. 1 is a functional block diagram illustrating an aspect of a distributed data processing environment;

FIG. 2 is a flowchart depicting an embodiment of operational steps of a predictive analytics program for predicting user touch events and providing targeted digital advertising to the user; and

FIG. 3 depicts a block diagram of an embodiment of the components of the server computer executing the predictive analytics program within the distributed data processing environment of FIG. 1.

### DETAILED DESCRIPTION

The following description is made for the purpose of illustrating the general principles of the present system and method and is not meant to limit the inventive concepts claimed herein. Further, particular features described herein can be used in combination with other described features in each of the various possible combinations and permutations.

Unless otherwise specifically defined herein, all terms are to be given their broadest possible interpretation including meanings implied from the specification as well as meanings understood by those skilled in the art and/or as defined in dictionaries, treatises, etc.

It must also be noted that, as used in the specification and the appended claims, the singular forms “a,” “an” and “the” include plural referents unless otherwise specified.

The prevalence and capabilities of client computing devices (e.g., smart watches, smart phones, smart televisions, laptop computers, tablet computers, etc.) is continually growing, as is the type of data capable of being collected by such computing devices. One such category of data is the electromagnetic (EM) noise signals emitted by both electronic and non-electronic objects. A client computing device equipped with an appropriate radio receiver may be capable of detecting the EM noise signals emitted by a variety of objects, even when the computing device itself is not in direct contact with the object(s). For example, a smart watch equipped with an appropriate radio receiver and worn on a user's wrist may be capable of detecting and recording unique EM noise signals (and associated metadata) generated by specific objects that the user interacts with on a day-to-day basis, such as appliances, vehicles, electromechanical devices, doors, furniture, etc. Based on this data, specific inferences and predictions about the user's daily activity patterns may be made, providing for more tangible data than simple geolocation information, and providing for additional data collection beyond manual data input by the user.

As set forth below, embodiments of the system and methods utilize EM noise signal detection to improve predictive analytics by providing information about a user's day-to-day experiences and patterns, and this information may be utilized to deliver targeted digital advertising to the user via, for example, one or more computing devices. Implementation of embodiments of the system and methods may take a variety of forms, and exemplary implementation details are discussed subsequently with reference to the Figures.

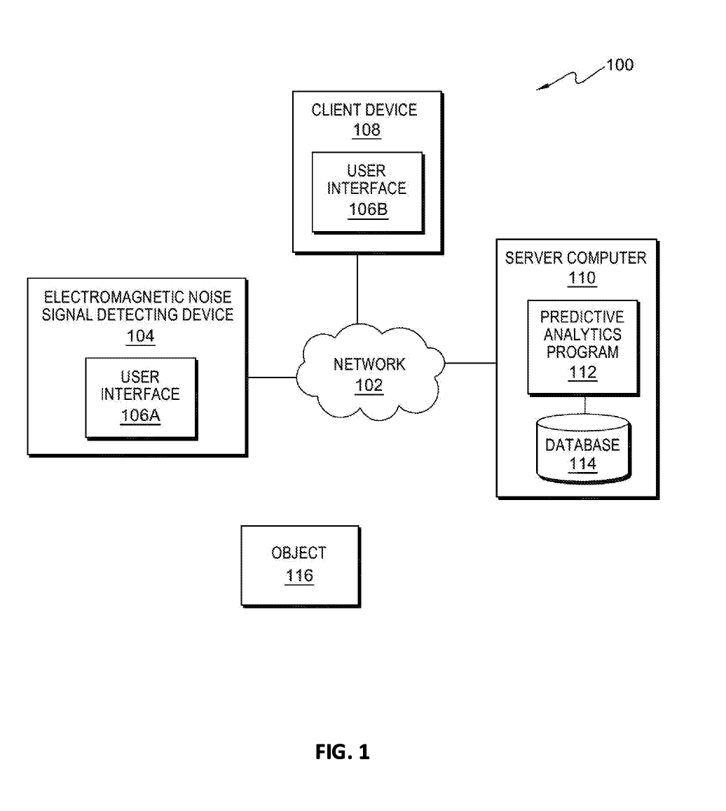

FIG. 1 is a functional block diagram in accordance with an embodiment illustrating a distributed data processing environment, generally designated 100. The term “distributed” as used in this specification describes a computer system that includes multiple, physically distinct devices that operate together as a single computer system. FIG. 1 provides only an illustration of one implementation and does not imply any limitations with regard to the environments, systems, or methods in which different embodiments may be implemented. Many modifications to the depicted environment may be made by those skilled in the art without departing from the scope of the disclosure as recited by the claims.

Distributed data processing environment 100 includes electromagnetic (EM) noise signal detecting device 104, client device 108, and server computer 110, all interconnected via network 102. An object 116 may also be associated with distributed data processing environment 100. Network 102 can be, for example, a telecommunications network, a local area network (LAN), a wide area network (WAN), such as the Internet, or any combination thereof. Furthermore, network 102 may include wired, wireless, or fiber optic connections. Network 102 can include one or more wired and/or wireless networks that are capable of receiving and transmitting data, voice, and/or video signals, including multimedia signals that include voice, data, and video information. In general, network 102 can be any combination of connections and protocols that will support communications between EM noise signal detecting device 104, client device 108, server computer 110, and optionally other computing devices (not shown) within distributed data processing environment 100.

EM noise signal detecting device 104 may be conductively associated to a user and may detect EM noise signals transmitted through a human body, as the human body is capable of conducting EM noise signals of various objects upon contact. EM noise signal detecting device 104 may comprise a software-defined radio receiver to act as a sensor adapted and configured to detect EM signals. For example, the software-defined radio receiver of EM noise signal detecting device 104 may have a sensing range of 1 Hz-28.8 MHz, thereby making it possible for EM noise signal detecting device 104 to detect low-band EM signals commonly present in various electrical and electromechanical objects.

EM noise signal detecting device 104 may transmit a detected EM noise signal and associated metadata to predictive analytics program 112, operating on server computer 110, via network 102. Metadata may include, but is not limited to, data such as a date, a time stamp, physical location (e.g., GPS coordinates), accumulated frequency of touch events, etc. EM noise signal detecting device 104 may be, for example, a smart watch, a laptop computer, a tablet computer, a smart phone, or any programmable electronic mobile device having an appropriate radio receiver capable of detecting EM noise signals conducted through an object during a touch event, and capable of communicating with various components and devices within distributed data processing environment 100 via network 102. In one embodiment, EM noise signal detecting device 104 may also be combined with or integrated into a client device, such as client device 108, which is capable of receiving, sending, and displaying data inputs from server computer 110. In general, EM noise signal detecting device 104 represents any electronic device or combination of electronic devices capable of detecting EM noise signals, executing machine-readable program instructions, and communicating with other computing devices, such as server computer 110 and client device 108, within distributed data processing environment 100 via a network, such as network 102. EM noise signal detecting device 104 may also include a user interface 106A.

Client device 108 may be a smart watch, a smart television, a laptop computer, a tablet computer, a smart phone, or any programmable electronic device capable of communicating with various components and devices within distributed data processing environment 100 via network 102. In an embodiment, client device 108 may be an electronic device configured to receive, send, and display data associated with user settings. Client device 108 may receive direct input from the user via user interface 106B, which may include identification of unrecognized EM noise signals or input for managing supervised learning activities. Client device 108 may represent any programmable electronic device, pre-configured electronic device, or combination of programmable and pre-configured electronic devices capable of executing machine readable program instructions and communicating with other computing devices (not shown) within distributed data processing environment 100 via a network, such as network 102. In another embodiment, client device 108 may be the same device as EM noise signal detecting device 104. For example, client device 108 may be a smart watch having EM noise signal detecting device 104 associated with and/or housed therein. In an alternative embodiment, client device 108 may be limited to communicating with other computing devices (not shown) within distributed data processing environment 100 via a network, such as network 102. In the depicted embodiment, client device 108 includes a user interface 106B. In another embodiment, client device 108 does not include a user interface 106B.

User interfaces 106A and 106B may provide an interface to predictive analytics program 112 on server computer 110 for a user of EM noise signal detecting device 104 or a user of client device 108. In one embodiment, user interface 106A and 106B may be graphical user interfaces (GUI) or web user interfaces (WUI) and can display text, documents, web browser windows, user options, application interfaces, and instructions for operation, and include the information (such as graphic, text, and sound) that a program presents to a user and the control sequences the user employs to control the program. In another embodiment, user interface 106A and 106B may also be mobile application software that provides an interface between a user of EM noise signal detecting device 104 or a user of client device 108 and server computer 110. Mobile application software, or an “app,” is a computer program designed to run on smart phones, smart watches, tablet computers, and other mobile devices. For example, user interface 106A and 106B may enable the user of EM noise signal detecting device 104 to register with and configure predictive analytics program 112 to adjust the tracking of EM noise signal touch events, such as user touch events associated with client device 108 or object 116, by the user of EM noise signal detecting device 104. In another example, user interface 106A and 106B may enable the user of client device 108 to communicate with predictive analytics program 112 to receive notifications and adjust user preferences.

Object 116 may be any EM noise signal emitting object, such as an electrical appliance, vehicle, electronic device, etc. Furthermore, object 116 may also be any non-EM noise signal emitting object or non-EM noise signal emitting component of a device that is capable of acting as a conduit of EM noise signals that are within detectable proximity of object 116, but not capable of communicating with other computing devices via a network, such as network 102. The proximity required for object 116 to act as a conduit of surrounding EM noise signals depends on the strength of EM noise signals, the sensitivity of EM noise signal detecting device 104, and a conductivity attribute of object 116, which can depend on factors such as the size, shape, and material of construction of object 116. For example, large structural components such as metallic doors, ladders, window frames, and furniture may be large enough to capture nearby EM energy. In an embodiment, EM noise signal detecting device 104 can detect the EM noise signal captured and propagated by object 116 through direct contact between a user of EM noise signal detecting device 104 and object 116. For example, EM noise signal detecting device 104, such as a smart watch, can detect the EM noise signal of a door handle, acting as object 116, when a user wearing a smart watch capable of detecting EM noise signals touches the handle to open the door. In another aspect, if EM noise signal detecting device 104, such as a smart watch, cannot connect to server computer 110, then EM noise signal detecting device 104 may send the information to client computing device 108 which can relay the information to server computer 110.

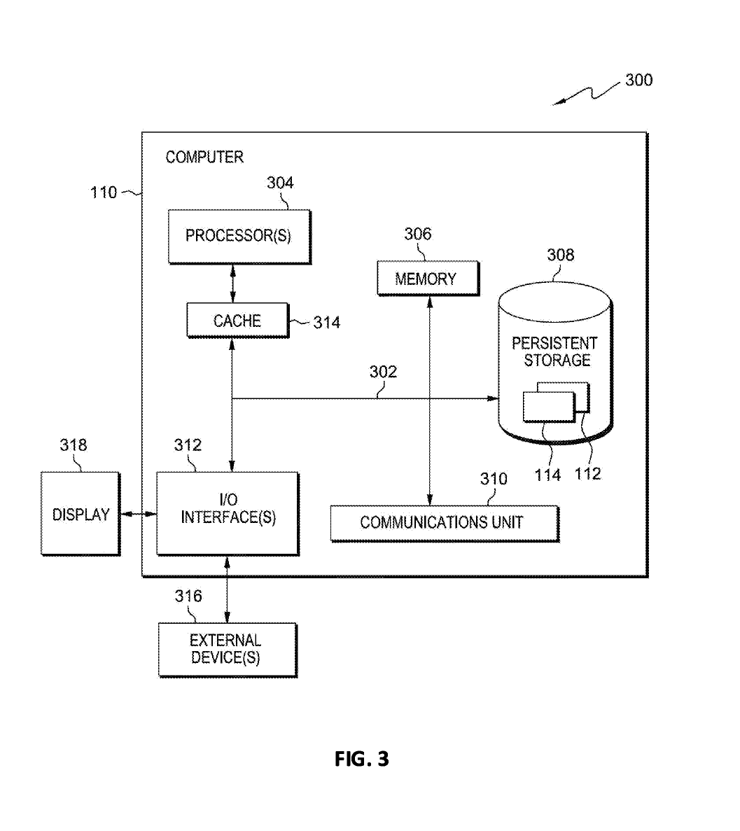

Server computer 110 may be a standalone computing device, a management server, a web server, a mobile computing device, or any other electronic device or computing system capable of receiving, sending, and processing data. In some embodiments, server computer 110 may represent a server computing system utilizing multiple computers as a server system, such as in a cloud computing environment. In another embodiment, server computer 110 can be a laptop computer, a tablet computer, a netbook computer, a personal computer (PC), a desktop computer, a personal digital assistant (PDA), a smart phone, or any other electronic device capable of communicating with EM noise signal detecting device 104, client device 108, and other computing devices (not shown) within distributed data processing environment 100 via network 102. In another embodiment, server computer 110 represents a computing system utilizing clustered computers and components (e.g., database server computers, application server computers, etc.) that act as a single pool of seamless resources when accessed within distributed data processing environment 100. Server computer 110 includes predictive analytics program 112 and database 114. Server computer 110 may include internal and external hardware components, as depicted and described in further detail with respect to FIG. 3.

Predictive analytics program 112 may execute a series of steps in order to predict a user touch event by applying predictive analytics to multiple previously-detected EM noise signals and the metadata associated with those multiple previously-detected EM noise signals. Predictive analytics program 112 may receive a detected EM noise signal of an object that a user touches or holds, such as an object 116 or client device 108. Predictive analytics program 112 may compare the received EM noise signal from the touched object to a database containing stored EM noise signals associated with various known objects and devices. Predictive analytics program 112 may attempt to identify the touched object associated with the received EM noise signal by comparison of the received EM noise signal to the various known object EM noise signals that are stored, for example, in database 114 on server computer 110. In one embodiment, if predictive analytics program 112 does not identify the touched object associated with the received EM noise signal, then predictive analytics program 112 may prompt a user to input metadata associated with the object, such as a descriptive name and/or the type of object and the location of the object, for future identification. Responsive to the user inputting metadata associated with the touched object, or if predictive analytics program 112 identifies the touched object, predictive analytics program 112 may store the metadata associated with the touched object in database 114 for future identification. For example, predictive analytics program 112 may make a prediction as to which object a user touched using confidence scores for particular objects. In another example, predictive analytics program 112 may identify the object based on a confidence score based on user feedback confirming the identity of the object in previous user touch events.

Database 114 may act as a repository for data used by predictive analytics program 112. In the depicted embodiment, database 114 resides on server computer 110. In another embodiment, database 114 may reside elsewhere within distributed data processing environment 100 provided predictive analytics program 112 has access to database 114. Database 114 can be implemented with any type of storage device capable of storing data and configuration files that can be accessed and utilized by server computer 110, such as a database server, a hard disk drive, or flash memory. Database 114 may store metadata which includes any data that predictive analytics program 112 may use to predict future user touch events. Database 114 may store the EM noise signal data and associated metadata of particular objects that conduct EM noise signals from operating electronic devices, which are within a proximity that is detectable by EM noise signal detecting device 104. Database 114 may also store metadata associated with the EM noise signal of an object such as object 116. Database 114 may also store data such as registration and configuration data of EM noise signal detecting device 104 and client device 108. Registration data may include, but is not limited to, data identifying a user who interacts with client device 108 and EM noise signal detecting device 104. Configuration data may include, but is not limited to, policies for identifying metadata that database 114 stores about particular objects or touch events in association with a particular user. Database 114 may also store EM noise signal standards that predictive analytics program 112 compares to the detected EM noise signals, and device data corresponding to the EM noise signal standards.

Predictive analytics program 112 may determine whether a quantity or frequency of user touch events stored as historical data associated with an object, such as client device 108 or object 116, meets a learning threshold. If the learning threshold is met, then predictive analytics program 112 may predict when an EM noise signal for the object will occur. That is, predictive analytics program 112 may predict future user touch events by establishing a pattern of user touch events correlating to user behavior, such as a date, a time stamp, a frequency of user touch events, a category of object being used, and objects touched before and after the touch event.

Similarly, predictive analytics program 112 may analyze user touch events over time in order to develop a characteristic profile of the user. For example, based on the EM noise signal sensed by the EM noise signal detecting device 104, the predictive analytics program 112 may determine that the user drives a vehicle each week, Monday through Friday, between 7:30 AM and 8:30 AM, and again between 4:45 PM and 5:45 PM, and that the user is in contact with a personal computer keyboard relatively consistently between the hours of 8:30 AM and 4:45 PM. Accordingly, the predictive analytics program 112 may profile the user as one who works at a computer throughout much of their day and who commutes to their place of employment by way of their own vehicle.

In another example, the predictive analytics program 112 may also determine that the user touches a stove around 6:00 PM each Sunday through Thursday, but that the user does not touch a stove at that same time each Friday and Saturday. With this information, the predictive analytics program 112 may profile the user as one who frequently dines outside of the home on Friday and Saturday evenings, yet prepares (or assists in preparing) their own meals on other evenings during the week. Again, this determination and prediction may be made based on the EM noise signal from a stove sensed by the EM noise signal detecting device 104.

While the above examples pertain to the determination of day-to-day activities by the user via EM noise signals sensed by the EM noise signal detecting device 104, it is to be understood that one or more characteristic user profile may be constructed by predictive analytics program 112 to cover an array of different categories. For example, the characteristic user profile may contain various demographic details regarding the user (e.g., age, occupation, etc.), various location-based categories (e.g., frequent use of certain public spaces, certain locations in the workplace, certain locations in the home, etc.), and/or various activity-based categories (e.g., preferred forms of entertainment, fitness, recreation, etc.). Other categories are also possible and are within the scope of aspects of the disclosure. The information used to form the characteristic user profile(s) may be obtained from various sources, such as the EM noise signal detecting device 104, direct user input (e.g., via a graphical user interface or web user interface), geophysical location information, etc., and/or combinations thereof.

Based on the characteristic user profile(s) generated by the predictive analytics program 112, various actions may be performed using the details and/or categories unique to the user profile(s). For example, in accordance with an aspect of the disclosure, predictive analytics program 112 may be utilized to display or otherwise deliver tailored digital advertisements to the user of client device 108, and predictive analytics program 112 may perform such an action at a program-determined time and manner. The digital advertisements may be any form of digital advertisement, such as banner advertisements on specific website pages, sponsored content on social media platforms, audio and/or video commercial advertisements on web-based media streaming platforms, direct-to-user text messaging, direct-to-user electronic mailing, etc. It is to be understood that aspects of the disclosure are not limited to the above-referenced examples, as other forms of digital advertisements are commonly utilized and are within the scope of the present disclosure.

In one example noted above, the predictive analytics program 112 may determine, via the EM noise signal received by EM noise signal detecting device 104, that unlike their typical daily routine each Sunday through Thursday, the user does not touch a stove at or around 6:00 PM on Friday and Saturday evenings. Thus, the predictive analytics program 112 may profile the user as one who frequently dines outside of the home on Friday and Saturday evenings. Utilizing this information and/or presumption, predictive analytics program 112 may deliver tailored digital advertisement(s) to the user at predetermined times via one or more digital platforms. For example, under the presumption that the user will be dining outside the home on a Friday evening, the predictive analytics program 112 may act to deliver a banner advertisement for a particular restaurant near the user's location. The timing of the specific banner advertisement may be optimized such that the likelihood that the user sees the advertisement prior to finalizing their dining plans is increased. For example, the banner advertisement may be shown to the user via a GUI, WUI, or other visual interface at least once between the hours of 8:00 AM and 5:00 PM on a Friday, thereby increasing the likelihood that the advertisement will be seen or heard by the user prior to them actually dining that evening. In this way, predictive analytics program 112 may provide tailored digital advertising to a user based at least in part on data received from the EM noise signal detecting device 104.

In another example, the predictive analytics program 112 may analyze the information pertaining to the user's vehicle use in order to tailor digital advertisements presented to the user that are centered around vehicles and vehicle use. As noted above, based on the EM noise signal sensed by the EM noise signal detecting device 104, the predictive analytics program 112 may determine that the user drives a vehicle each week, Monday through Friday, between 7:30 AM and 8:30 AM, and again between 4:45 PM and 5:45 PM. With this information, the predictive analytics program 112 may ascertain that the user commutes to their place of employment in their own vehicle each weekday, and that their commute is relatively long-distance (i.e., one hour, each way). Accordingly, digital advertisements from, e.g., automobile manufacturers, automobile dealers, automobile service centers, etc., may be provided to the user via various electronic means throughout the day, as this particular user may be more likely to purchase a new vehicle, require frequent service on their current vehicle(s), etc. The timing of these digital advertisements may be optimized. For example, an audio advertisement may be specifically delivered over a digital streaming platform during the user's commute. However, it is to be understood that such optimized timing is not required. Conversely, if the EM noise signal detecting device 104 worn or associated with another, second user does not detect (or infrequently detects) EM noise signals indicative of vehicle use, digital advertisements from automobile manufacturers, automobile dealers, automobile service centers, etc. to the second user may be avoided, as second user would likely not fall into the preferred target audience of the advertiser(s).

In accordance with another aspect of the disclosure, as the characteristic user profile and/or user classification is stored in database 114, the predictive analytics program 112 may deliver tailored digital advertisements to the user, even on occasions that the EM noise signal detecting device 104 is not continuously active, worn by the user, associated with the user, etc. For example, the user may only wear the EM noise signal detecting device 104 (e.g., a smart watch) for a period of time necessary to allow the predictive analytics program 112 to adequately construct a characteristic user profile and/or user classification based on EM noise signals detected by the EM noise signal detecting device 104. After a general characteristic user profile and/or user classification has been constructed, predictive analytics program 112 may have adequate information about the user's behavior and preferences to deliver accurate, tailored digital advertisements to the user, without the need for constant feedback from the EM noise signal detecting device 104.

In addition to the information received from the EM noise signal detecting device 104, predictive analytics program 112 may also utilize information from other sources when constructing a user profile. For example, “mobile extensions” such as locations determined via GPS, weather conditions, “Internet of Things” (or IoT) information, social media profiles, etc. may be combined with the EM noise signal information in order for the predictive analytics program 112 to construct an accurate and/or more beneficial user profile for use in targeted digital advertising.

As described above, predictive analytics program 112 may receive various inputs in order to construct the one or more characteristic user profile(s), with the inputs being a set of point events describing a touched object (e.g., via an EM profile of known objects) and the time at which the touch event occurred. Such events are then analyzed using a statistical model on order to categorize the user's behavior and/or tendencies. One such statistical model which may be used is a Hidden Markov Model (HMM). Hidden Markov Models may be advantageous for such predictive analytics, as they allow for the modeling of a “hidden” internal state which, in this instance, represents an activity being performed by the user. Specifically, a Hierarchical Hidden Markov Model (HHMM) may be used in accordance with aspects of the disclosure. However, it is to be understood that any appropriate statistical modeling process may be used in accordance with aspects of the disclosure.

With a Hierarchical Hidden Markov Model, the user's behavior and/or tendencies may be modeled as a set of transitions between a series of different states, and each state may itself be analyzed via another Hierarchical Hidden Markov Model. Accordingly, relatively complex human behavior may be modeled. The highest level of the Hierarchical Hidden Markov Model would broadly represent an overall activity (e.g., cooking, driving a vehicle, etc.), and each overall activity may contain its own Hierarchical Hidden Markov Model. For instance, during the broad activity of cooking, the user likely transitions between various predictable states (e.g., ingredient preparation, opening an oven door, cleaning, etc.), each of which may form an “event” detectable by the EM noise signal detecting device 104. The detected event information would allow for training of the model by associating the low-level transitions (e.g., transition from ingredient preparation to opening the oven door) with specific device usage (e.g., cooking using an oven). Such training of the model thereby builds an overall pattern of behavior of the user, which may be utilized by digital advertisers as detailed above. The model acts to translate specific point elements of user behavior to long-term states, with the Hidden Markov Model capable of identifying how often the user is in these long-term states (i.e., how often the user is carrying out a certain activity).

When a complete model such as, for example, a Hierarchical Hidden Markov Model, is constructed, the top-level behaviors and/or tendencies of the user (and the degrees to which the user engages in those behaviors/tendencies) may be used to classify the user into a specific category or segment. Such classification may be generated using any of a variety of known statistical classification models, such as Decision Trees, Hierarchical Clustering, k-Means, Nearest Neighbor, etc.

Alternatively and/or additionally, classification approaches other than Hidden Markov Models may be utilized in accordance with the disclosure. For example, a set of point events identifying an item touched by the user (e.g., a stove), the time at which these point events occurred (e.g., between 6:00 PM and 6:15 PM), and the duration of the point events may be utilized to help construct a user profile and classify the user. The classification modeling framework in accordance with this aspect may utilize one or more of Support Vector Machines (SVM), random forest, gradient boost machines, Extreme Gradient Boosting (“XGBoost”), and/or other suitable classifiers in order to classify any known users into different categories.

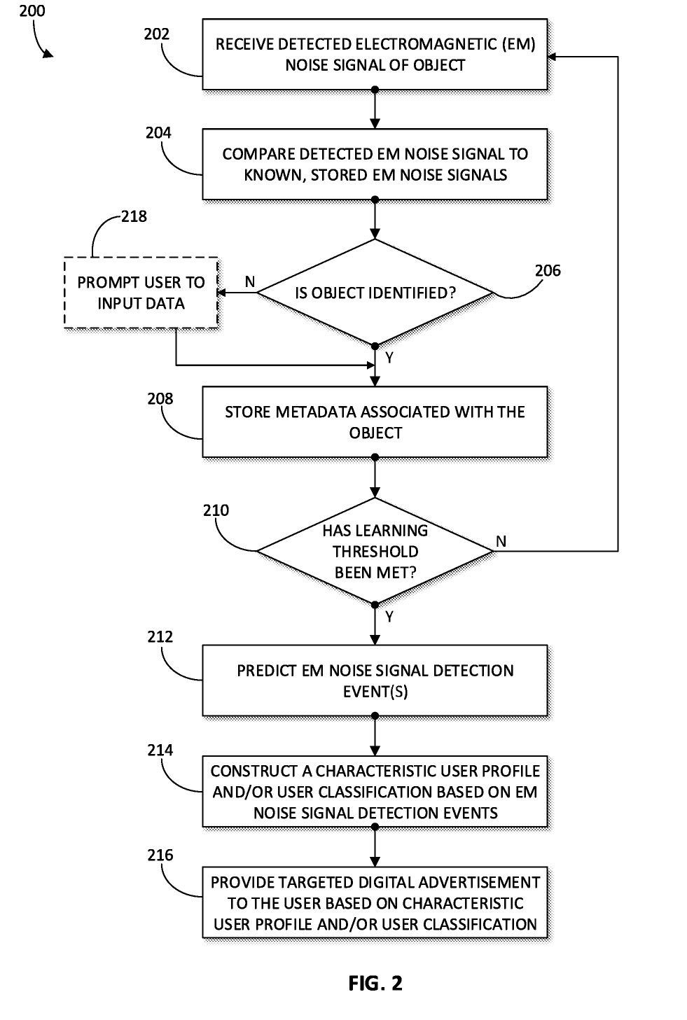

Next, referring now to FIG. 2, an operation process 200 of predictive analytics program 112 is depicted and described in further detail. FIG. 2 illustrates a flowchart depicting operational process 200 of predictive analytics program 112 for predicting user touch events by analyzing gathered EM noise signal data and subsequently providing the user with one or more tailored digital advertisements based on the predicted user touch events, in accordance with an aspect of the present disclosure. While process 200 may be considered for the sake of convenience and not with the intent of limiting the disclosure as comprising a series and/or number of steps, it is to be understood that the process may be integrated and one or more steps may be performed together, and the process does not need be performed as a series of steps and/or the steps do not need to be performed in the order shown and described with respect to FIG. 2.

At 202, predictive analytics program 112 receives a detected EM noise signal of an object from EM noise signal detecting device 104 via, for example, network 102. As disclosed above, in one aspect, EM noise signal detecting device 104 conductively couples with a user who makes contact with an object, such as by touching client device 108 or object 116, and detects an EM noise signal unique to the object. For example, in an embodiment where EM noise signal detecting device 104 is a smart watch equipped with a radio receiver, a user conducts the EM noise signal through the user's body while touching various EM noise emitting or EM noise capturing objects, thereby enabling the smart watch to detect the EM noise signal.

At 204, predictive analytics program 112 compares the received EM noise signal to stored EM noise signals. In one embodiment, database 114 includes known EM noise signal standards and stored EM noise signals resulting from one or more user touch events of an electronic or electromagnetic object, such as client device 108 or object 116. Predictive analytics program 112 compares the received EM noise signal from the object contacted by a user touch event to the EM noise signals stored within database 114. For example, a user conductively coupled with EM noise signal detecting device 104 touches the handle of a stove (i.e., a user touch event). EM noise signal detecting device 104 detects the EM noise signal conducted through the stove handle and user, and transmits the EM noise signal to predictive analytics program 112, residing on, for example, server computer 110, via network 102. In the example, predictive analytics program 112 compares the received EM noise signal associated with the stove handle to the EM noise signals stored in database 114.

At 206, predictive analytics program 112 may attempt to identify an object associated with the received EM noise signal. Based on the comparison in 204, predictive analytics program 112 attempts to match the received EM noise signal of the device or object touched by the user with a stored EM noise signal. As described above, the object may be an electronic, electromechanical, non-electronic, or non-electromechanical object.

If predictive analytics program 112 does not identify the object associated with the received EM noise signal (“no” at 206), then predictive analytics program 112 may prompt the user to input data associated with the object at 218. For example, the prompt generated by predictive analytics program 112 may be a text message sent to user interface 106 on client device 108 asking the user to input data associated with the unidentified object, such as the type of object, the brand of the object, the location of the object, etc. However, the user may also input any recordable data regarding the object. In accordance with another, alternative aspect of the disclosure, step 218 may be omitted. That is, if “no” at 206, process 200 may simply end without prompting the user to manually input data associated with an unidentified object.

Responsive to prompting the user to input data associated with the object, or if predictive analytics program 112 identifies the object (“yes” at 206), predictive analytics program 112 stores metadata associated with the identified object at 208. The metadata may include any data that may be used to predict future user touch events by establishing a pattern of user touch events correlating to user behavior, such as a date, a time stamp, a frequency of user touch events, a category of object being used, and objects touched before and after the touch event. Further, predictive analytics program 112 may be configured to store different types of metadata depending on the category of object and circumstances surrounding a user touch event. For example, predictive analytics program 112 may store metadata regarding the objects touched before and after the user touch event only if they fall within a pre-determined timeframe of the touch event. In another example, predictive analytics program 112 may only continue storing time stamp and date metadata for objects that a user touches on a frequent or consistent basis, such as a stove that is touched every evening between certain hours for a consecutive period of days sufficient to establish a pattern of behavior. In accordance with an aspect of the disclosure, predictive analytics program 112 may automatically identify additional metadata associated with the identified object to be stored. For example, predictive analytics program 112 may identify the configured metadata storage policies for the object and identify the relevant metadata to be stored for the object.

At 210, predictive analytics program 112 determines whether a learning threshold is met. A learning threshold is met when a pre-determined quantity of metadata associated with prior user touch events for an object is available to enable predictive analytics program 112 to predict an EM noise signal touch event with a pre-determined confidence level by establishing a pattern of user behavior. In some aspects of the systems and methods, the learning threshold may be the same for all objects, while in other aspects, the learning threshold may be unique to each object. Additionally, the determination of a learning threshold depends on the existence of a quantity of data, such as instances of a user touch event, to establish a pattern of user behavior.

Predictive analytics program 112 may determine the learning threshold using any predictive analytics algorithm or combination of algorithms including, but not limited to, a time series forecast, or a supervised learning classifier. In one embodiment, predictive analytics program 112 may use a time series forecast to predict a future user touch event based on past observed values. For example, predictive analytics program 112 may collect a multitude of instances of a user of EM noise signal detecting device 104 touching a stove at certain times of the day, for consecutive days. Based on the multitude of recorded instances of the user touch event of the stove, predictive analytics program 112 may create a time series model in response to collecting a pre-determined quantity of data to predict future user touch events at an acceptable confidence level. In another example, predictive analytics program 112 may have sufficient metadata to meet a learning threshold but the quantity of recent or current user touch event instance data points necessary to establish the learning threshold may change.

In cases in which EM noise signal detecting device 104 does not consistently add metadata to the time series model, confidence levels may be inadequate to maintain the learning threshold. In a related example, the aforementioned scenario can occur when a user changes the data patterns by changing their behavior such as beginning to touch a device like a stove at a later time of day than usual, perhaps because of a lengthier work commute. In another example, predictive analytics program 112 may utilize a supervised learning classifier to execute a regression analysis to predict the likelihood of future EM noise signal detection events using recorded metadata. For example, predictive analytics program 112 may collect a multitude of instances of a user of EM noise signal detecting device 104 touching a stove and determine the times of day that the touch events occurred. Utilizing the metadata, predictive analytics program 112 may determine an algorithm that best fits the data pattern to predict, with pre-determined confidence levels, particular EM noise signal detection events occurring at different times of the day and determine a user's pattern of behavior. The disclosure is not limited by the aforementioned embodiments and may use any predictive analytics algorithm and any recordable metadata to define a learning threshold.

If predictive analytics program 112 determines that the learning threshold is not met (“no” at 210), then predictive analytics program 112, having stored the instance and metadata of the touch event instance in step 208, returns to step 202 to receive additional detected EM noise signals. However, if “yes” at 210, responsive to a determination that the learning threshold is met, at 212, predictive analytics program 112 predicts a time and circumstance of a future EM noise signal detection event, such as a user touch event, associated with one or more objects, such as client device 108 or object 116. For example, predictive analytics program 112 may determine that there is a high confidence level, such as a 70% chance, that a user will touch a stove between 6:00 P.M. and 6:15 P.M. each Monday through Thursday evening. In another example, predictive analytics program 112 may determine that there is a high likelihood that the user will touch an electric toothbrush between 7:00 A.M. and 7:15 A.M. every day of the week, between 10:30 P.M. and 10:45 P.M. every weeknight, and between 12:00 A.M. and 12:15 A.M. every weekend night. However, predictive analytics program 112 is not limited by the aforementioned embodiments and may make predictions based on metadata associated with the historical record of user touch events of one or more objects, such as electronic objects, electromechanical objects, and non-electronic or electromechanical objects acting as EM noise signal propagating antennas.

At 214, predictive analytics program 112 utilizes the predicted EM noise signal detection events in order to construct a characteristic profile of the user and classify the user into one or more categories. For example, as disclosed above, predictive analytics program 112 may infer that because a user does not touch a stove on Friday and Saturday evenings (as determined through user touch events, or lack thereof), the user is likely to dine outside the home. Accordingly, the predictive analytics program 112 may include in the characteristic user profile and/or user classification that the user is likely to frequent restaurants or other dining establishments, particularly on Friday and Saturday evenings. As disclosed above, the user profile and classification may be generated through a variety of statistical modeling methods.

At 216, predictive analytics program 112 performs an action to display or otherwise provide a targeted digital advertisement to the user based on the characteristic user profile and/or user classification. For example, as the characteristic user profile suggests that the user will be dining outside the home on a Friday evening, the predictive analytics program 112 may act to deliver a banner advertisement for a particular restaurant near the user's location. The timing of the specific banner advertisement may be optimized such that the likelihood that the user sees the advertisement prior to finalizing their dining plans is increased. For example, the banner advertisement may be shown to the user via a GUI, WUI, or other visual interface at least once between the hours of 8:00 AM and 5:00 PM on a Friday, thereby increasing the likelihood that the advertisement will be seen or heard by the user prior to them actually dining that evening. It is to be understood that any form of digital advertisement, be it visual, audible, or otherwise, may be provided to the user based on their characteristic user profile and/or user classification.

Referring now to FIG. 3, a block diagram of an embodiment of the components of server computer 110 within distributed data processing environment 100 of FIG. 1 are illustrated. It should be appreciated that FIG. 3 provides only an example of one implementation and does not imply any limitations with regard to the environments, systems, or methods in which different embodiments can be implemented. Many modifications to the depicted environment, systems, and/or methods can be made.

Server computer 110 can include processor(s) 304, cache 314, memory 306, persistent storage 308, communications unit 310, input/output (I/O) interface(s) 312 and communications fabric 302. Communications fabric 302 provides communications between cache 314, memory 306, persistent storage 308, communications unit 310, and input/output (I/O) interface(s) 312. Communications fabric 302 can be implemented with any architecture designed for passing data and/or control information between processors (such as microprocessors, communications and network processors, etc.), system memory, peripheral devices, and any other hardware components within a system. For example, communications fabric 302 can be implemented with one or more buses.

Memory 306 and persistent storage 308 are computer readable storage media. In this embodiment, memory 306 includes random access memory (RAM). In general, memory 306 can include any suitable volatile or non-volatile computer readable storage media. Cache 314 is a fast memory that enhances the performance of processor(s) 304 by holding recently accessed data, and data near recently accessed data.

Program instructions and data used to practice embodiments of the systems and methods, e.g., predictive analytics program 112 and database 114, are stored in persistent storage 308 for execution and/or access by one or more of the respective processor(s) 304 of server computer 110 via cache 314. In this embodiment, persistent storage 308 includes a magnetic hard disk drive. Alternatively, or in addition to a magnetic hard disk drive, persistent storage 308 can include a solid-state hard drive, a semiconductor storage device, a read-only memory (ROM), an erasable programmable read-only memory (EPROM), a flash memory, or any other computer readable storage media that is capable of storing program instructions or digital information.

The media used by persistent storage 308 may also be removable. For example, a removable hard drive may be used for persistent storage 308. Other examples include optical and magnetic disks, thumb drives, data storage cartridges, and smart cards that are inserted into a drive for transfer onto another computer readable storage medium that is also part of persistent storage 308.

Communications unit 310, in these examples, provides for communications with other data processing systems or devices, including resources of EM noise signal detecting device 104 and client device 108. In these examples, communications unit 310 includes one or more network interface cards. Communications unit 310 may provide communications through the use of either or both physical and wireless communications links. Predictive analytics program 112, database 114, and other programs and data used for implementation, may be downloaded to persistent storage 308 of server computer 110 through communications unit 310.

I/O interface(s) 312 allows for input and output of data with other devices that may be connected to server computer 110. For example, I/O interface(s) 312 may provide a connection to external device(s) 316 such as a keyboard, a keypad, a touch screen, a microphone, a digital camera, and/or some other suitable input device. External device(s) 316 can also include portable computer readable storage media such as, for example, thumb drives, portable optical or magnetic disks, data storage cartridges, and memory cards. Software and data used to practice embodiments of the systems and methods, e.g., predictive analytics program 112 and database 114 on server computer 110, can be stored on such portable computer readable storage media and can be loaded onto persistent storage 308 via I/O interface(s) 312. I/O interface(s) 312 may also connect to a display 318.

Display 318 provides a mechanism to display data to a user and may be, for example, a computer monitor or display screen. Display 318 can also function as a touchscreen, such as a display of a tablet computer.

The programs described herein are identified based upon the application for which they are implemented in a specific aspect of the disclosure. However, it should be appreciated that any particular program nomenclature herein is used merely for convenience, and thus the disclosure should not be limited to use solely in any specific application identified and/or implied by such nomenclature.

The present disclosure may be a system, a method, and/or a computer program product. The computer program product may include a computer readable storage medium (or media) having computer readable program instructions thereon for causing a processor to carry out aspects of the present disclosure.

The computer readable storage medium can be any tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present disclosure may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, a special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present disclosure. In this regard, each block in the flowchart or block diagrams may represent a module, a segment, or a portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the disclosure. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A method for providing one or more targeted digital advertisements to a user, the method comprising:
receiving, by one or more computer processors, a detected electromagnetic noise signal of one or more objects;
comparing, by the one or more computer processors, the detected electromagnetic noise signal of the one or more objects to one or more stored electromagnetic noise signals associated with one or more objects;
determining, by the one or more computer processors, an identity of the one or more objects based on the comparison between the detected electromagnetic noise signal of the one or more objects to one or more stored electromagnetic noise signals associated with one or more objects; and
providing, by the one or more computer processors, one or more targeted digital advertisements to the user based on the determined identity of the one or more objects.

2. The method of claim 1, further comprising:
constructing, by the one or more computer processors, at least one of a characteristic user profile and a user classification based on the determined identity of the one or more objects.

3. The method of claim 2, wherein the at least one of the characteristic user profile and the user classification is constructed using at least one statistical model.

4. The method of claim 3, wherein the at least one statistical model is at least one of a Hidden Markov Model and a Hierarchical Hidden Markov Model.

5. The method of claim 3, wherein the at least one statistical model used to construct the user classification is selected from at least one of the group consisting of: Decision Trees, Hierarchical Clustering, k-Means, Nearest Neighbor, Support Vector Machines, random forest, gradient boost machines, Extreme Gradient Boosting, and combinations thereof.

6. The method of claim 1, further comprising:
predicting, by the one or more computer processors, one or more subsequent electromagnetic noise signal detection events associated with the one or more objects.

7. The method of claim 6, further comprising:
storing, by the one or more computer processors, metadata corresponding to one or more electromagnetic noise signal detection events associated with the identified one or more objects; and
determining, by the one or more computer processors, whether a quantity and a frequency of recorded metadata corresponding to the one or more electromagnetic signal detection events associated with the one or more objects meets a learning threshold prior to predicting the one or more subsequent electromagnetic noise signal detection events associated with the one or more objects.

8. The method of claim 1, further comprising prompting, by the one or more computer processors, a user to input metadata associated with the object.

9. The method of claim 1, wherein receiving the detected electromagnetic noise signal of one or more objects comprises receiving the detected electromagnetic noise signal from one or more of a smart watch, a smart phone, a smart television, a laptop computer, and a tablet computer equipped with a radio receiver.

10. The method of claim 1, wherein providing the one or more targeted digital advertisements to the user comprises at least one of providing one or more banner advertisements on one or more website pages, providing sponsored content on one or more social media platforms, providing at least one of audio and video commercial advertisements on one or more web-based media streaming platforms, providing direct-to-user text messaging, and providing direct-to-user electronic mailing.

11. The method of claim 1, wherein providing the one or more targeted digital advertisements to the user comprises providing the one or more targeted digital advertisements at a predetermined time based on the predicted one or more subsequent electromagnetic noise signal detection events.

12. A computer program product for providing one or more targeted digital advertisements to a user, the computer program product comprising:
one or more computer readable storage devices having a non-transitory, computer-readable memory containing program instructions stored thereon, the stored program instructions comprising:
program instructions to receive a detected electromagnetic noise signal of one or more objects;
program instructions to compare the detected electromagnetic noise signal of the one or more objects to one or more stored electromagnetic noise signals associated with one or more objects;
based, at least in part, on the comparison, program instructions to determine an identity of the one or more objects; and
based, at least in part, on the determined identity of the one or more objects, program instructions to provide one or more targeted digital advertisements to the user.

13. The computer program product of claim 12, the stored program instructions further comprising:
responsive to determining the identity of the object, program instructions to predict one or more subsequent electromagnetic noise signal detection events associated with the one or more objects; and
program instructions to construct at least one of a characteristic user profile and a user classification based on the one or more predicted subsequent electromagnetic noise signal detection events.

14. The computer program product of claim 12, the stored program instructions further comprising:
responsive to determining the identity of the one or more objects, program instructions to store metadata corresponding to an electromagnetic noise signal detection event associated with the one or more objects;
program instructions to determine whether a quantity and a frequency of recorded metadata corresponding to the electromagnetic signal detection event associated with the one or more object meets a learning threshold.

15. The computer program product of claim 12, wherein providing the one or more targeted digital advertisements to the user comprises program instructions to provide one or more banner advertisements on one or more website pages, provide sponsored content on one or more social media platforms, provide at least one of audio and video commercial advertisements on one or more web-based media streaming platforms, provide direct-to-user text messaging, and provide direct-to-user electronic mailing.

16. The computer program product of claim 12, wherein providing the one or more targeted digital advertisements to the user comprises program instructions to provide the one or more targeted digital advertisements at a predetermined time based on the predicted one or more subsequent electromagnetic noise signal detection events.

17. A computer system for providing one or more targeted digital advertisements to a user, the computer system comprising:
one or more computer processors;
one or more computer readable storage devices;
program instructions stored on the one or more computer readable storage devices for execution by at least one of the one or more computer processors, the stored program instructions comprising:
program instructions to receive a detected electromagnetic noise signal of one or more objects;
program instructions to compare the detected electromagnetic noise signal of the one or more objects to one or more stored electromagnetic noise signals associated with one or more objects;
based, at least in part, on the comparison, program instructions to determine an identity of the one or more objects; and
based, at least in part, on the determined identity of the one or more objects, program instructions to provide one or more targeted digital advertisements to the user.

18. The computer system of claim 17, the stored program instructions further comprising:
responsive to determining the identity of the object, program instructions to predict one or more subsequent electromagnetic noise signal detection events associated with the one or more objects; and
program instructions to construct at least one of a characteristic user profile and a user classification based on the one or more predicted subsequent electromagnetic noise signal detection events.

19. The computer system of claim 17, the stored program instructions further comprising:
responsive to determining the identity of the one or more objects, program instructions to store metadata corresponding to an electromagnetic noise signal detection event associated with the one or more objects;
program instructions to determine whether a quantity and a frequency of recorded metadata corresponding to the electromagnetic signal detection event associated with the one or more object meets a learning threshold.

20. The computer system of claim 17, wherein the characteristic user profile is constructed using a statistical model, further wherein the statistical model is at least one of a Hidden Markov Model and a Hierarchical Hidden Markov Model.
